(19) United States
(12) Patent Application Publication
(10) Pub. No.: US 2026/0163566 A1
(43) Pub. Date: Jun. 11, 2026

(54) SWITCH DEVICE AND CONTROL METHOD THEREOF

(71) Applicant: RichWave Technology Corp., Taipei (TW)

(72) Inventors: Meng-Lun Li, Taipei (TW); Tien-Yun Peng, Taipei (TW); Chih-Sheng Chen, Taipei (TW)

(73) Assignee: RichWave Technology Corp., Taipei (TW)

(21) Appl. No.: 19/007,564

(22) Filed: Jan. 2, 2025

(30) Foreign Application Priority Data
Dec. 11, 2024 (TW) 113148065

(51) Int. Cl. H03K 17/16

(52) U.S. Cl. CPC H03K 17/162

(57) ABSTRACT

A switch device and a control method thereof are provided. The switch device includes a receiving circuit. The receiving circuit includes a receiving series circuit. The receiving series circuit includes multiple receiving series transistors coupled in series with each other. The receiving series transistors includes at least one first receiving series transistor and at least one second receiving series transistor. When the switch device executes a first mode, the at least one first receiving series transistor is turned on, and the at least one second receiving series transistor is cut off. When the switch device executes a second mode, the at least one first receiving series transistor is turned on, and the at least one second receiving series transistor is turned on.

### CROSS-REFERENCE TO RELATED APPLICATION

This application claims the priority benefit of Taiwan application serial no. 113148065, filed on Dec. 11, 2024. The entirety of the above-mentioned patent application is hereby incorporated by reference herein and made a part of this specification.

### BACKGROUND

### Technical Field

The disclosure relates to a switch device and its control method, and particularly to a switch device and a control method thereof which may improve switching efficiency.

### Related Art

In the conventional switch device, when the switch device is switched to a bypass mode, a parasitic capacitor on the receiving series transistor of a receiving series circuit thereof may store a certain amount of accumulated charge which may not be released. When the switch device is switched from the bypass mode to a receiving mode, these accumulated charges may generate a voltage difference at an input terminal of a corresponding low noise amplifier of the switch device, increase stabilization time of an internal current generated by the low noise amplifier, and thereby reduce switching efficiency of the switch device.

### SUMMARY

The disclosure provides a switch device and a control method thereof, which may reduce a problem of generating accumulated charges which is unable to be released on a receiving series transistor of a receiving circuit under a bypass mode.

A switch device of the disclosure includes a receiving circuit. The receiving circuit is coupled between a first terminal and a second terminal. The receiving circuit includes a receiving series circuit, where a first terminal of the receiving series circuit is coupled to the first terminal, and a second terminal of the receiving series circuit is coupled to the second terminal. The receiving series circuit is composed of multiple receiving series transistors connected in series, and the receiving series transistors are composed of at least one first receiving series transistor and at least one second receiving series transistor. When the switch device executes a first mode, the at least one first receiving series transistor is turned on, and the at least one second receiving series transistor is cut off. When the switch device executes a second mode, the at least one first receiving series transistor is turned on, and the at least one second receiving series transistor is turned on.

In an embodiment of the disclosure, a control method of the switch device includes following steps. A receiving circuit coupled between a first terminal and a second terminal is provided. Multiple receiving series transistors connected in series are provided to compose a receiving series circuit, where the receiving series circuit is coupled between the first terminal and the second terminal, and the receiving series transistors are composed of at least one first receiving series transistor and at least one second receiving series transistor. In a first mode, at least one first receiving series transistor is made to be turned on, and at least one second receiving series transistor is made to be cut off. In a second mode, at least one first receiving series transistor is made to be turned on, and at least one second receiving series transistor is made to be turned on.

Based on the above, in the switch device of the disclosure, the receiving circuit is composed of the receiving series transistors. In the second mode, the receiving series transistors of the receiving circuit may all be turned on to execute a signal receiving action. In the first mode, which is not the second mode, among the receiving series transistors, a part of one or multiple first receiving series transistors may be turned on, while another part of one or multiple second receiving series transistors may be cut off. The accumulated charges on the receiving series circuit may be released by the first receiving series transistors which are turned on, thereby reducing possibility of affecting a switching action of the switch device.

### BRIEF DESCRIPTION OF THE DRAWINGS

FIG. 1 is a schematic diagram of a switch device according to an embodiment of the disclosure.

FIG. 2A is a schematic diagram of a switch device according to another embodiment of the disclosure.

FIG. 2B is a schematic diagram of an implementation manner of a shunt circuit according to an embodiment of the disclosure.

FIG. 3 is a schematic diagram of a switch device according to another embodiment of the disclosure.

FIG. 4 is a schematic diagram of a control signal of a shunt transistor TD1 of a switch device 300.

FIG. 5A and FIG. 5B are schematic diagrams of other implementation manners of a receiving shunt circuit on a receiving circuit 310 of the switch device 300.

FIG. 6 is a flowchart of a control method of a switch device according to an embodiment of the disclosure.

### DESCRIPTION OF THE EMBODIMENTS

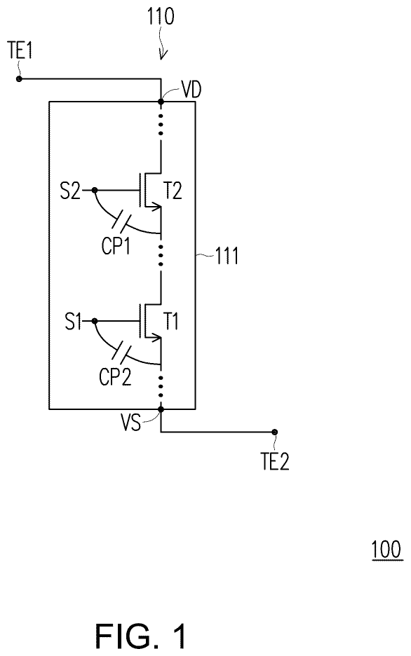

Please refer to FIG. 1, which is a schematic diagram of a switch device according to an embodiment of the disclosure. A switch device 100 includes a receiving circuit 110. The receiving circuit 110 is coupled between a first terminal TE1 and a second terminal TE2. In this embodiment, the first terminal TE1 may be a signal transceiving terminal. The second terminal TE2 may be a transmission terminal for receiving signals. In details, the first terminal TE1 may be coupled to an antenna terminal, for example, while the second terminal TE2 may be coupled to an amplifier (such as a low noise amplifier) configured to process received signals.

The receiving circuit 110 includes a receiving series circuit 111. The receiving series circuit 111 has a first terminal VD and a second terminal VS. The first terminal VD of the receiving series circuit 111 is coupled to the first terminal TE1, while the second terminal VS of the receiving series circuit 111 is coupled to the second terminal TE2. The receiving series circuit 111 may be composed of multiple receiving series transistors coupled in series with each other. In this embodiment, the receiving series transistors include one or multiple receiving series transistors T1 and one or multiple receiving series transistors T2. The receiving series transistors T2 and T1 are sequentially coupled between the first terminal VD and the second terminal VS.

In this embodiment, the receiving series transistor T1 may be controlled by a control signal S1, while the receiving series transistor T2 may be controlled by a control signal S2. In this embodiment, depending on different working modes, the receiving series transistors T1 and

T2 may be respectively turned on or cut off according to the control signals S1 and S2 which are controlled. Furthermore, in this embodiment, taking the receiving series transistors T1 and T2 as metal-oxide-semiconductor field-effect transistors (MOSFETs) for example, there may be a parasitic capacitor CP2 between a control terminal and a source terminal of the receiving series transistor T1, and there may be a parasitic capacitor CP1 between a control terminal and a source terminal of the receiving series transistor T2. Accumulated charges may be generated in the parasitic capacitors CP1 and CP2.

In detail, when the switch device 100 executes a second mode, the receiving series transistors T1 and T2 may both be in a turned-on status. In this status, the signal received at the first terminal TE1 may be transmitted to the second terminal TE2 by the turned-on receiving series transistors T1 and T2. In other words, in this embodiment, the second mode may be a signal receiving mode.

Furthermore, when the switch device 100 switches from the second mode to a first mode, the receiving series transistor T1 may be maintained in a turned-on status, while the receiving series transistor T2 may change to be in a cut-off status. In this status, the receiving series transistor T2 which is made to be in the cut-off status may block the signal at the first terminal TE1 from being transmitted to the second terminal TE2. Additionally, the receiving series transistor T1 which is maintained in the turned-on status may provide a release path for the accumulated charges in the parasitic capacitors CP1 and CP2, and thereby reduce the release time needed for releasing the accumulated charges in the receiving series circuit 111.

It is worth mentioning that when the switch device 100 enters the first mode, according to some embodiments of the disclosure, the receiving series transistor T2 is made to be in the turned-on status, and the receiving series transistor T1 is made to be in the cut-off status.

In the first mode, a ratio of a number of receiving series transistors T1 set up to be in the turned-on status to a number of receiving series transistors T2 set up to be in the cut-off status may be greater than or equal to 0.2 and less than or equal to 5, in order to obtain better switch efficiency and reduce the release time needed for releasing the accumulated charges in the receiving series circuit 111. In some embodiments of the disclosure, the number of receiving series transistors T1 set up to be in the turned-on status may be the same as the number of receiving series transistors T2 set up to be in the cut-off status.

Incidentally, in the embodiment of the disclosure, the receiving series transistors T1 and T2 may be N-type transistors. In other embodiments of the disclosure, the receiving series transistors T1 and T2 may also be P-type transistors, without any specific limitation.

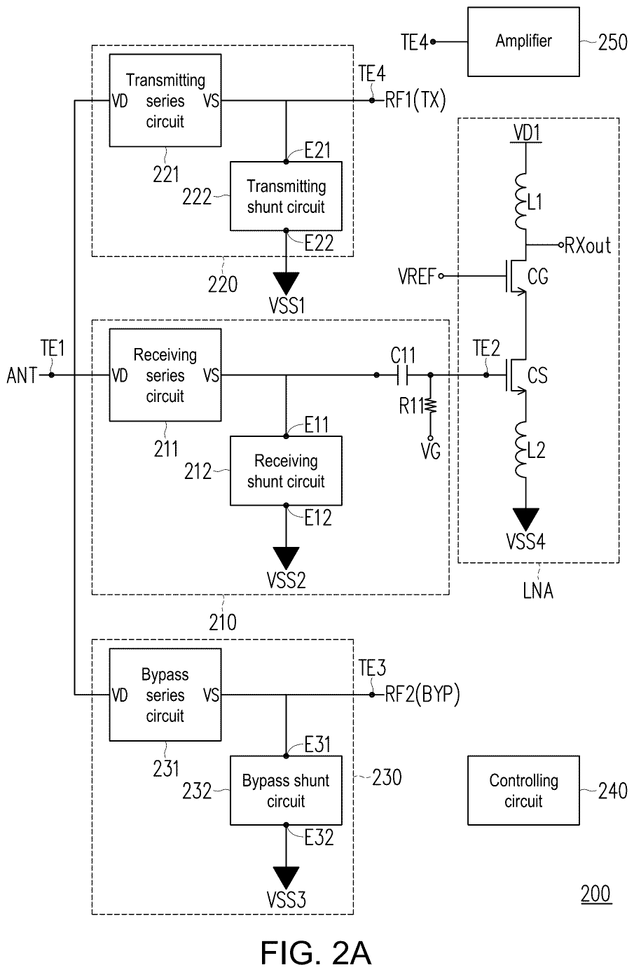

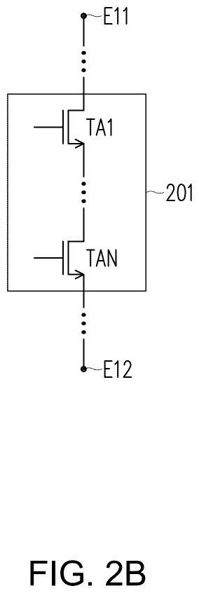

Please refer to FIG. 2A below. FIG. 2A is a schematic diagram of a switch device according to another embodiment of the disclosure. A switch device 200 includes a receiving circuit 210, a transmitting circuit 220, a bypass circuit 230, and a controlling circuit 240. The receiving circuit 210 is coupled between the first terminal TE1 and the second terminal TE2. The first terminal TE1 is also coupled to an antenna ANT, while the second terminal TE2 is coupled to a low noise amplifier LNA. The receiving circuit 210 includes a receiving series circuit 211 and a receiving shunt circuit 212. Furthermore, in some embodiments, the receiving circuit 210 may further include a capacitor C11 and a resistor R11. A first terminal VD of the receiving series circuit 211 is coupled to the first terminal TE1, while a second terminal VS of the receiving series circuit 211 is coupled to the second terminal TE2, for example, by the capacitor C11. A first terminal E11 of the receiving shunt circuit 212 is coupled between the second terminal VS of the receiving series circuit 211 and the second terminal TE2, and a second terminal E12 of the receiving shunt circuit 212 is coupled to a reference voltage terminal VSS2. Additionally, the capacitor C11 may be coupled between the second terminal VS of the receiving series circuit 211 and the second terminal TE2. The capacitor C11 is a DC decoupling capacitor, which may be configured to filter out a DC component of the receiving signal at the second terminal VS of the receiving series circuit 211, and transmit an AC component of the receiving signal at the second terminal VS of the receiving series circuit 211 to the low noise amplifier LNA. One terminal of the resistor R11 is coupled to the second terminal TE2, and another terminal of the resistor R11 is coupled to a bias terminal VG. The resistor R11 may be configured to reduce the risk of the receiving signal (a radio frequency signal) leaking to the bias terminal VG in the second mode.

FIG. 2B is a schematic diagram of an implementation manner of the shunt circuit according to an embodiment of the disclosure. Further, the receiving shunt circuit 212 in FIG. 2A may be implemented by using a circuit architecture of the shunt circuit 201 in FIG. 2B. The shunt circuit 201 includes series-coupled shunt transistors TA1 to TAN. In a situation where the shunt circuit 201 in FIG. 2B is applied to the receiving shunt circuit 212 in FIG. 2A, the receiving shunt circuit 212 may be considered as composed of one or multiple receiving shunt transistors TA1 to TAN connected in series to each other, and the receiving shunt transistors TA1 to TAN may be coupled between the first terminal E11 and the second terminal E12 of the shunt circuit 212.

In this embodiment, when the switch device 200 executes the first mode, the receiving shunt transistors TA1 to TAN of the receiving shunt circuit 212 may all be in a turned-on status. Meanwhile, a part of the receiving series transistors (referring to the receiving series transistor T1) of the receiving series circuit 211 may be in a turned-on status, while another part of the receiving series transistors (referring to the receiving series transistor T2) of the receiving series circuit 211 may be in a cut-off status. The aforementioned first mode may be a bypass mode.

In another aspect, when the switch device 200 executes the second mode, at least part of the receiving shunt transistors TA1 to TAN of the receiving shunt circuit 212 may be in a cut-off status. Meanwhile, all of the receiving series transistors of the receiving series circuit 211 may be in the turned-on status. The aforementioned second mode may be a signal receiving mode.

The bypass circuit 230 is coupled between the first terminal TE1 and a third terminal TE3. The bypass circuit 230 includes a bypass series circuit 231 and a bypass shunt circuit 232. A first terminal VD of the bypass series circuit 231 is coupled to the first terminal TE1, while a second terminal VS of the bypass series circuit 231 is coupled to the third terminal TE3. The bypass series circuit 231 is composed of multiple bypass series transistors connected in series to each other, and a circuit architecture thereof is similar to a circuit architecture of the receiving series circuit 111 in FIG. 1. In other words, in a situation where the receiving series circuit 111 in FIG. 1 is applied to the bypass series circuit 231 in FIG. 2A, the receiving series transistors T1 and T2 may be considered as the aforementioned bypass series transistors. The bypass series circuit 231 is not further described here.

A first terminal E31 of the bypass shunt circuit 232 is coupled between the second terminal VS of the bypass series circuit 231 and the third terminal TE3. A second terminal E32 of the bypass shunt circuit 232 is coupled to the reference voltage terminal VSS3. The bypass shunt circuit 232 is composed of multiple bypass shunt transistors connected in series to each other, and a circuit architecture thereof may be similar to the circuit architecture of the shunt circuit 201 in FIG. 2B. In other words, in a situation where the shunt circuit 201 in FIG. 2B is applied to the bypass shunt circuit 232 in FIG. 2A, the shunt transistors TA1 to TAN may be considered as the aforementioned bypass shunt transistors. The bypass shunt circuit 232 is not further described here.

In this embodiment, the third terminal TE3 may be configured to transmit a radio frequency signal RF2 (BYP) in the first mode (the bypass mode).

Regarding the operation details, when the switch device 200 executes the first mode, all of the bypass series transistors of the bypass series circuit 231 may be in a turned-on status, while the bypass shunt transistors of the bypass shunt circuit 232 may be in a cut-off status. When the switch device 200 executes the second mode (the receiving mode), all of the bypass series transistors of the bypass series circuit 231 may be in a cut-off status, while the bypass shunt transistors of the bypass shunt circuit 232 may be in a turned-on status.

In addition, the transmitting circuit 220 is coupled between the first terminal TE1 and a fourth terminal TE4. The transmitting circuit 220 includes a transmitting series circuit 221 and a transmitting shunt circuit 222. A first terminal VD of the transmitting series circuit 221 is coupled to the first terminal TE1, and a second terminal VS of the transmitting series circuit 221 is coupled to the fourth terminal TE4. The transmitting series circuit 221 is composed of multiple transmitting series transistors connected in series to each other, and a circuit architecture thereof is similar to the architecture of the receiving series circuit 111 in FIG. 1. In other words, in a situation where the receiving series circuit 111 in FIG. 1 is applied to the transmitting series circuit 221 in FIG. 2A, the receiving series transistors T1 and T2 may be considered as the aforementioned transmitting series transistors. The transmitting series circuit 221 is not further described here.

A first terminal E21 of the transmitting shunt circuit 222 is coupled between the second terminal VS of the transmitting series circuit 221 and the fourth terminal TE4. A second terminal E22 of the transmitting shunt circuit 222 is coupled to a reference voltage terminal VSS1. The transmitting shunt circuit 222 is composed of multiple series-connected transmitting shunt transistors, and a circuit architecture thereof may be similar to the circuit architecture of the shunt circuit 201 in FIG. 2B. In other words, in a situation where the shunt circuit 201 in FIG. 2B is applied to the transmitting shunt circuit 222 in FIG. 2A, the shunt transistors TA1 to TAN may be considered as the aforementioned transmitting shunt transistors. The transmitting shunt circuit 222 is not further described here.

When the switch device 200 operates in a third mode (a transmitting mode), all of the transmitting series transistors of the transmitting series circuit 221 may be turned on, while the transmitting shunt transistors of the transmitting shunt circuit 222 may be cut off. The fourth terminal TE4 may receive the radio frequency signal RF (TX) in the transmitting mode, and transmit the radio frequency signal RF (TX) to the first terminal TE1 by the transmitting series circuit 221, so that the radio frequency signal RF (TX) may be transmitted to the antenna ANT.

The controlling circuit 240 is coupled to the receiving circuit 210, the transmitting circuit 220, and the bypass circuit 230. The controlling circuit 240 may generate multiple control signals to control the turned-on and cut-off statuses of the transistors of the receiving circuit 210, the transmitting circuit 220, and the bypass circuit 230. It is worth noting that, whether in the first mode, the second mode, or the third mode, based on a fact that the turned-on and cut-off statuses of all transmitting shunt transistors of the transmitting shunt circuit 222 and the receiving series transistor T1 of the receiving series circuit 211 are the same, the controlling circuit 240 may be configured to provide the same control signal to control all transmitting shunt transistors of the transmitting shunt circuit 222 and the receiving series transistor T1 of the receiving series circuit 211 to perform the same operation. Further, when the switch device 200 executes the first mode (for example, the bypass mode), all transmitting shunt transistors of the transmitting shunt circuit 222 and the receiving series transistor T1 of the receiving series circuit 211 are all turned on. When the switch device 200 executes the second mode (for example, the receiving mode), all transmitting shunt transistors of the transmitting shunt circuit 222 and the receiving series transistor T1 of the receiving series circuit 211 are all turned on. When the switch device 200 executes the third mode (for example, the transmitting mode), all transmitting shunt transistors of the transmitting shunt circuit 222 and the receiving series transistor T1 of the receiving series circuit 211 are all cut off.

In this embodiment, the low noise amplifier LNA may include, for example, inductors L1 and L2 and transistors CG and CS. The transistors CG and CS are sequentially coupled in series, the inductor L1 is coupled between a reference voltage VD1 and a first terminal (for example, a drain thereof) of the transistor CG, and the inductor L2 is coupled between a reference voltage VSS4 and a second terminal (for example, a source thereof) of the transistor CS. A control terminal of the transistor CG receives a reference voltage VREF, and a control terminal of the transistor CS is coupled to the second terminal TE2. The control terminal of the transistor CS may be an input terminal of the low noise amplifier LNA. A first terminal of the transistor CG may be an output terminal of the low noise amplifier LNA and may be configured to generate an output signal RXout.

Moreover, when the switch device 200 executes the second mode (the receiving mode), the receiving circuit 210 is configured to receive a signal from the first terminal TE1 and transmit the signal to the second terminal TE2, so that the signal may be transmitted to the input terminal of the low noise amplifier LNA.

Incidentally, in this embodiment of the disclosure, the third terminal TE3 may be coupled to the output terminal of the low noise amplifier LNA. When the switch device 200 executes the first mode (the bypass mode), the bypass circuit 230 is configured to receive a signal (that is, the radio frequency signal RF2 (BYP)) from the first terminal TE1 and transmit the signal to the third terminal TE3, so that the signal may not be amplified by the low noise amplifier LNA.

In addition, in this embodiment of the disclosure, the switch device 200 may also include an amplifier 250. The amplifier 250 may be, for example, a power amplifier. An output terminal of the amplifier 250 may be coupled to the fourth terminal TE4. When the switch device 200 executes the third mode (the transmitting mode), the amplifier 250 may provide a signal to the fourth terminal TE4. The transmitting circuit 220 is configured to receive a signal (that is, a radio frequency signal RF1 (TX)) from the fourth terminal TE4, transmit the signal to the first terminal TE1, and then transmit the signal to the antenna ANT by the first terminal TE1.

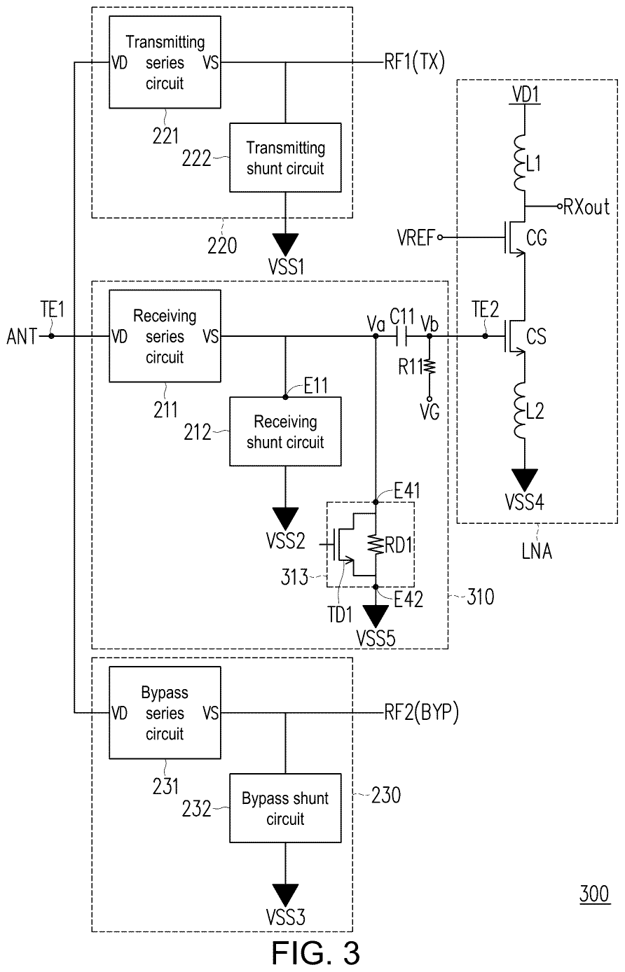

Please refer to FIG. 3, which is a schematic diagram of a switch device according to another embodiment of the disclosure. A switch device 300 includes a receiving circuit 310, a transmitting circuit 220, a bypass circuit 230, a controlling circuit 240, and a low noise amplifier LNA. In this embodiment, circuit architectures and embodiment details of the transmitting circuit 220, the bypass circuit 230, the controlling circuit 240, and the low noise amplifier LNA are the same as those in the implementation of FIG. 2A and FIG. 2B, and are not further described here.

Unlike the aforementioned embodiments, the receiving circuit 310 in this embodiment includes a receiving series circuit 211 and receiving shunt circuits 212 and 313. In addition, in some embodiments, the receiving circuit 210 may further include a capacitor C11 and a resistor R11. The relevant descriptions of the receiving series circuit 211, the receiving shunt circuit 212, the capacitor C11, and the resistor R11 have been described in detail in the embodiments of FIG. 2A and FIG. 2B, and are not repeated here. It is worth noting that a first terminal E41 of a receiving shunt circuit 313 may be coupled between the first terminal E11 of the receiving shunt circuit 212 and the second terminal TE2, while a second terminal E42 of the receiving shunt circuit 313 may be coupled to a reference voltage terminal VSS5. The receiving shunt circuit 313 includes a resistor RD1 and a receiving shunt transistor TD1. The resistor RD1 and the receiving shunt transistor TD1 may be coupled in parallel with each other.

In this embodiment of the disclosure, when the switch device 300 operates in the second mode (the receiving mode), the receiving shunt transistor TD1 may be turned on during a first period and may be cut off during a second period. The first period is an initial period of the second mode, and a time length of the first period is shorter than a time length of the second period.

The following table shows the operating statuses of the transistors of the receiving series circuit 211, the receiving shunt circuit 212 and 313 of the receiving circuit 310 of the switch device 300 of this embodiment under different modes:

| | Receiving series | Receiving shunt | Receiving shunt |
|---|---|---|---|
| Mode | circuit 211 | circuit 212 | circuit 313 |
| Bypass | Partially turned-on | Turned-on | Cut-off |
| mode | and partially cut-off | | |
| Receiving | Turned-on | Cut-off | Turned-on first and |
| mode | | | then cut-off |

In this embodiment of the disclosure, the time length of the first period may be, for example, greater than or equal to 150 nanoseconds and less than or equal to 230 nanoseconds. A resistance value of the resistor RD1 may be, for example, greater than or equal to 22 kilohms and less than or equal to 44 kilohms.

When the switch device 300 does not operate in the second mode, the receiving shunt transistor TD1 may be in a constant cut-off status.

In another aspect, when the switch device 300 executes the first mode (the bypass mode), an impedance seen from the first terminal E41 (equivalent to a node Va) of the receiving shunt circuit 313 towards the reference voltage terminal VSS5 may be a first impedance. When the switch device 300 executes the second mode (the receiving mode) and is in the aforementioned first period, an impedance seen from the first terminal E41 (equivalent to the node Va) of the receiving shunt circuit 313 towards the reference voltage terminal VSS5 may be a second impedance. During the first period, by making the node Va have a relatively low impedance value, the accumulated charge in the receiving series circuit 211 may be released to the reference voltage terminal VSS5 through the receiving shunt transistor TD1 which is turned on.

Moreover, when the switch device 300 executes the second mode and is in the aforementioned second period, an impedance seen from the first terminal E41 (equivalent to the node Va) of the receiving shunt circuit 313 towards the reference voltage terminal VSS5 is a third impedance, and the third impedance is greater than the first impedance and also greater than the second impedance. During the second period, the switch device 300 executes normal signal receiving operation, the receiving shunt circuit 313 is cut off, and the impedance at the node Va is a high impedance.

Please refer to the following table, which shows the impedance status at the nodes Va and Vb of the switch device 300 in this embodiment under different modes:

| Mode | Node Va | Node Vb |
|---|---|---|
| Third mode | Low | High |
| (Transmitting mode) | | |
| First mode | Low | High |
| (Bypass mode) | | |
| (Second mode) | Low to high | Low |
| (Receiving mode) | | |

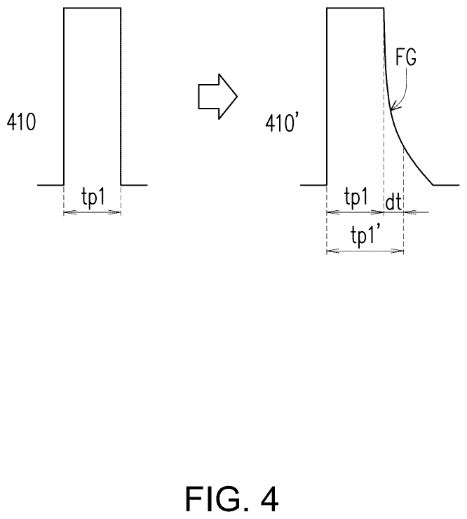

Please refer to FIG. 3 and FIG. 4 together, where FIG. 4 is a schematic diagram of a control signal of the receiving shunt transistor TD1 of the switch device 300. The receiving shunt transistor TD1 is taken as an N-type transistor for example. In an embodiment of the disclosure, a control signal 410 received by a control terminal of the receiving shunt transistor TD1 may be a pulse voltage. Moreover, the control signal 410 may be a positive pulse voltage during a period tP1 (equivalent to the aforementioned first period), and may be 0 voltage after the period tP1 (equivalent to the aforementioned second period). In this embodiment, the receiving shunt transistor TD1 may be fully turned on during the period tP1, and may be quickly cut off after the period tP1.

In another implementation manner of the disclosure, the control signal 410 may be changed to a control signal 410′. The control signal 410′ may have a positive pulse voltage during the period tP1, and have a falling edge FG with a delay time after the period tP1. By giving the falling edge FG of the control signal 410′ a delay time dt, the turned-on period of the receiving shunt transistor TD1 (equivalent to the aforementioned first period) may be extended by a delay time dt, that is, a time length of the first period is changed to a time length of a period tP1′. In this way, more accumulated charge in the receiving series circuit 211 may be released to the reference voltage terminal VSS5 through the receiving shunt transistor TD1 which is turned on. It should be noted that a voltage of the control signal 410′ is not necessarily 0 voltage after the delay time dt ends, but a low voltage that is low enough to make the receiving shunt transistor TD1 be cut off.

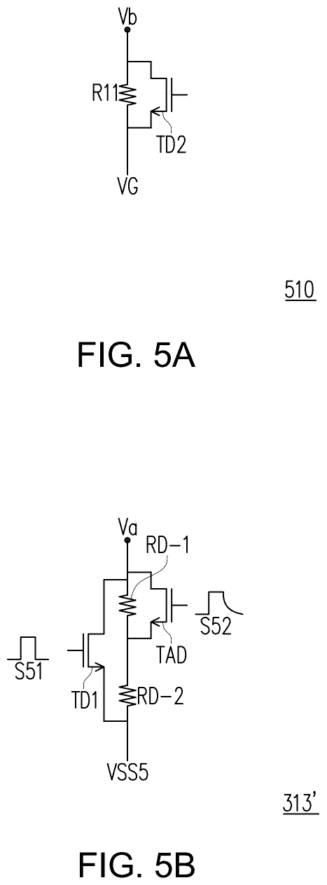

Please refer to FIG. 3, FIG. 5A, and FIG. 5B together, where FIGS. 5A and 5B are schematic diagrams of other embodiments of the receiving shunt circuit on the receiving circuit 310 of the switch device 300. In FIG. 5A, a receiving shunt transistor TD2 in conjunction with the resistor R11 may be disposed at the node Vb to form another receiving shunt circuit 510. The receiving shunt transistor TD2 and the resistor R11 are connected in parallel between the node Vb and the bias terminal VG. The receiving shunt transistor TD2 may execute the same operation as the receiving shunt transistor TD1 in the aforementioned embodiment. The receiving shunt circuit 510 coupled to the node Vb and the receiving shunt circuit 313 coupled to the node Va may be applied simultaneously in the embodiment of FIG. 3, which may further assist to release the accumulated charge in the receiving series circuit 211.

It is worth noting that in the embodiment of FIG. 3 of the disclosure, the resistor R11 alone may also compose the receiving shunt circuit 510.

In FIG. 5B, the receiving shunt circuit 313 in FIG. 3 may be changed to a receiving shunt circuit 313′ of FIG. 5B. The receiving shunt circuit 313′ may include a resistor RD-1, a resistor RD-2, a receiving shunt transistor TD1, and a receiving shunt transistor TAD. It may be considered that the resistor RD1 of the receiving shunt circuit 313 in FIG. 3 is split into the resistor RD-1 and the resistor RD-2 coupled in series to each other, with a second terminal of the resistor RD-1 coupled to a first terminal of the resistor RD-2. The resistor RD-1 and the resistor RD-2 are connected in series between the node Va and the reference voltage terminal VSS5. Two terminals of the receiving shunt transistor TD1 are connected across the node Va and the reference voltage terminal VSS5, and a first terminal of the receiving shunt transistor TD1 is coupled to a first terminal of the resistor RD-1, while a second terminal of the receiving shunt transistor TD1 is coupled to a second terminal of the resistor RD-2. A first terminal of another receiving shunt transistor TAD is coupled to the node Va and the first terminal of the resistor RD-1, and a second terminal of the receiving shunt transistor TAD is coupled to the mutual coupling terminals of the resistor RD-1 and the resistor RD-2, that is, the second terminal of the resistor RD-1 and the first terminal of the resistor RD-2.

The control terminals of the receiving shunt transistors TD1 and TAD receive control signals S51 and S52 respectively. The control signal S51 is a pulse voltage, while the control signal S52 is another pulse voltage with a delayed falling edge. The receiving shunt transistor TD1 in FIG. 5B may operate correspondingly to the receiving shunt transistor TD1 in FIG. 3 and the control signal 410 on a left side of FIG. 4, while the receiving shunt transistor TAD in FIG. 5B may operate correspondingly to the control signal 410′ on a right side of FIG. 4, and the operation manner of the aforementioned first period and second period is followed. The resistor RD-2 may reduce the risk of the receiving signal (the radio frequency signal) at the node Va leaking to the reference voltage terminal VSS5.

It is worth noting that the receiving shunt circuit 510 in FIG. 5A may also be changed to a circuit architecture of the receiving shunt circuit 313′ in FIG. 5B. The relevant details are not further described.

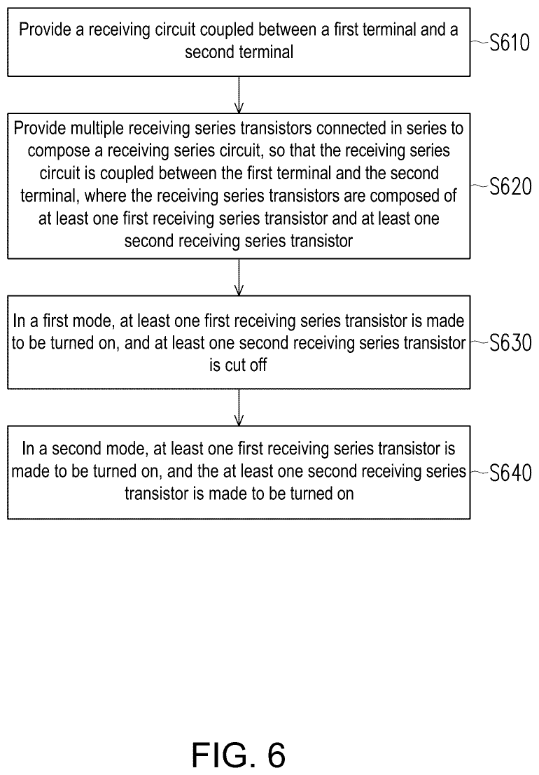

Please refer to FIG. 6, which is a flowchart of a control method of a switch device according to an embodiment of the disclosure. In step S610, a receiving circuit coupled between a first terminal and a second terminal is provided. In step S620, multiple receiving series transistors connected in series are provided to compose a receiving series circuit, so that the receiving series circuit is coupled between the first terminal and the second terminal. The receiving series transistors are composed of at least one first receiving series transistor and at least one second receiving series transistor. In step S630, in a first mode, at least one first receiving series transistor is made to be turned on, and at least one second receiving series transistor is made to be cut off. In step S640, in a second mode, at least one first receiving series transistor is made to be turned on, and at least one second receiving series transistor is made to be turned on.

Regarding the implementation details of the aforementioned steps, detailed descriptions have been provided in the aforementioned embodiments and implementation manners, and are not further described here.

In summary, in the receiving series circuit of the switch device of the disclosure, in a first mode, a part of the receiving series transistors is made to be turned on, and another part of the receiving series transistors is made to be cut off. In this way, the receiving series transistors which are maintained in the turned-on status may provide a release path for the accumulated charge in the receiving circuit, and the switching efficiency of the switch device may be improved by releasing the accumulated charge rapidly.

What is claimed is:

1. A switch device, comprising:
a receiving circuit, coupled between a first terminal and a second terminal, and comprising:
a receiving series circuit, wherein a first terminal of the receiving series circuit is coupled to the first terminal, a second terminal of the receiving series circuit is coupled to the second terminal, the receiving series circuit comprises a plurality of receiving series transistors connected in series, and the receiving series transistors are composed of at least one first receiving series transistor and at least one second receiving series transistor; wherein
when the switch device executes a first mode, the at least one first receiving series transistor is turned on, and the at least one second receiving series transistor is cut off; and
when the switch device executes a second mode, the at least one first receiving series transistor is turned on, and the at least one second receiving series transistor is turned on.

2. The switch device according to claim 1, wherein a ratio of a number of the at least one first receiving series transistor to a number of the at least one second receiving series transistor is greater than or equal to 0.2 and less than or equal to 5.

3. The switch device according to claim 1, wherein the at least one second receiving series transistor is coupled to the first terminal, the at least one first receiving series transistor is coupled between the at least one second receiving series transistor and the second terminal.

4. The switch device according to claim 1, wherein the receiving circuit further comprising:
a first receiving shunt circuit, wherein a first terminal of the first receiving shunt circuit is coupled between the second terminal of the receiving series circuit and the second terminal, a second terminal of the first receiving shunt circuit is coupled to a first reference voltage terminal, and the first receiving shunt circuit is composed of one or a plurality of first receiving shunt transistors connected in series; wherein
when the switch device executes the first mode, the one or plurality of first receiving shunt transistors are all turned on; and
when the switch device executes the second mode, at least part of the one or plurality of first receiving shunt transistors are cut off.

5. The switch device according to claim 1, further comprising:
a bypass circuit, coupled between the first terminal and a third terminal, and comprising:
a bypass series circuit, wherein a first terminal of the bypass series circuit is coupled to the first terminal, a second terminal of the bypass series circuit is coupled to the third terminal, and the bypass series circuit is composed of a plurality of bypass series transistors connected in series; and
a bypass shunt circuit, wherein a first terminal of the bypass shunt circuit is coupled between the second terminal of the bypass series circuit and the third terminal, a second terminal of the bypass shunt circuit is coupled to a second reference voltage terminal, and the bypass shunt circuit is composed of a plurality of bypass shunt transistors connected in series; wherein
when the switch device executes the first mode, the plurality of bypass series transistors are turned on, and the plurality of bypass shunt transistors are cut off; and
when the switch device executes the second mode, the plurality of bypass series transistors are cut off, and the plurality of bypass shunt transistors are turned on.

6. The switch device according to claim 1, further comprising:
a transmitting circuit, coupled between the first terminal and a fourth terminal, and comprising:
a transmitting series circuit, wherein a first terminal of the transmitting series circuit is coupled to the first terminal, a second terminal of the transmitting series circuit is coupled to the fourth terminal, and the transmitting series circuit is composed of a plurality of transmitting series transistors connected in series; and
a transmitting shunt circuit, wherein a first terminal of the transmitting shunt circuit is coupled between the second terminal of the transmitting series circuit and the fourth terminal, a second terminal of the transmitting shunt circuit is coupled to a reference voltage terminal, and the transmitting shunt circuit is composed of a plurality of transmitting shunt transistors connected in series; and
a controlling circuit, providing a first control signal to control the plurality of transmitting shunt transistors and the at least one first receiving series transistor to perform the same operation.

7. The switch device according to claim 4, wherein the receiving circuit further comprises:
a second receiving shunt circuit, wherein a first terminal of the second receiving shunt circuit is coupled between the first terminal of the first receiving shunt circuit and the second terminal, and a second terminal of the second receiving shunt circuit is coupled to a second reference voltage terminal.

8. The switch device according to claim 7, wherein the second receiving shunt circuit comprises a first resistor and a second receiving shunt transistor connected in parallel.

9. The switch device according to claim 8, wherein when the switch device executes the second mode, the second receiving shunt transistor is turned on during a first period, the second receiving shunt transistor is cut off during a second period, the first period is an initial period of the second mode, and a time length of the first period is shorter than a time length of the second period.

10. The switch device according to claim 9, wherein
when the switch device executes the first mode, an impedance seen from the first terminal of the second receiving shunt circuit towards the second reference voltage terminal is a first impedance;
when the switch device executes the second mode and is in the first period, an impedance seen from the first terminal of the second receiving shunt circuit towards the second reference voltage terminal is a second impedance; and
when the switch device executes the second mode and is in the second period, an impedance seen from the first terminal of the second receiving shunt circuit towards the second reference voltage terminal is a third impedance, the third impedance is greater than the first impedance, and the third impedance is greater than the second impedance.

11. The switch device according to claim 7, wherein the second receiving shunt circuit comprises a first resistor, a second resistor, a second receiving shunt transistor, and a third receiving shunt transistor, the first resistor is connected in series with the second resistor, a first terminal of the second receiving shunt transistor is coupled to a first terminal of the first resistor, a second terminal of the second receiving shunt transistor is coupled to a second terminal of the second resistor, a second terminal of the first resistor is coupled to a first terminal of the second resistor, a first terminal of the third receiving shunt transistor is coupled to the first terminal of the first resistor, and a second terminal of the third receiving shunt transistor is coupled to the second terminal of the first resistor.

12. The switch device according to claim 11, wherein the second receiving shunt transistor is controlled by a first pulse voltage, and the third receiving shunt transistor is controlled by a second pulse voltage with a falling edge having a delay time.

13. The switch device according to claim 9, wherein the receiving circuit further comprises a third receiving shunt circuit, a first terminal of the third receiving shunt circuit is coupled between the first terminal of the second receiving shunt circuit and the second terminal, and a second terminal of the third receiving shunt circuit is coupled to a bias terminal.

14. The switch device according to claim 13, wherein the third receiving shunt circuit comprises a third resistor.

15. The switch device according to claim 14, wherein the third receiving shunt circuit further comprises a fourth receiving shunt transistor connected in parallel with the third resistor, and when the switch device executes the second mode, the fourth receiving shunt transistor is turned on during a first period, and the fourth receiving shunt transistor is cut off during a second period.

16. The switch device according to claim 14, wherein the third receiving shunt circuit further comprises a fourth resistor, a fourth receiving shunt transistor and a fifth receiving shunt transistor, the third resistor is connected in series with the fourth resistor, a first terminal of the fourth receiving shunt transistor is coupled to a first terminal of the third resistor, a second terminal of the fourth receiving shunt transistor is coupled to a second terminal of the fourth resistor, a second terminal of the third resistor is coupled to a first terminal of the fourth resistor, a first terminal of the fifth receiving shunt transistor is coupled to the first terminal of the third resistor, and a second terminal of the fifth receiving shunt transistor is coupled to the second terminal of the third resistor.

17. The switch device according to claim 1, further comprising a low noise amplifier, wherein the second terminal is coupled to an input terminal of the low noise amplifier, and when the switch device executes the second mode, the receiving circuit is configured to receive a first signal from the first terminal and transmit the first signal to the second terminal, so that the first signal is transmitted to the low noise amplifier.

18. The switch device according to claim 5, further comprising a low noise amplifier, wherein the second terminal is coupled to an input terminal of the low noise amplifier, the third terminal is coupled to an output terminal of the low noise amplifier, and when the switch device executes the first mode, the bypass circuit is configured to receive a first signal from the first terminal and transmit the first signal to the third terminal, so that the first signal is not amplified by the low noise amplifier.

19. The switch device according to claim 6, further comprising an amplifier, wherein an output terminal of the amplifier is coupled to the fourth terminal, and when the switch device executes a third mode, the transmitting circuit is configured to receive a second signal from the fourth terminal and transmit the second signal to the first terminal.

20. A control method of a switch device, comprising:
providing a receiving circuit coupled between a first terminal and a second terminal, wherein the receiving circuit comprises a receiving series circuit, a first terminal of the receiving series circuit is coupled to the first terminal, a second terminal of the receiving series circuit is coupled to the second terminal, the receiving series circuit comprises a plurality of receiving series transistors connected in series with each other, and the receiving series transistors are composed of at least one first receiving series transistor and at least one second receiving series transistor;
in a first mode, making the at least one first receiving series transistor be turned on, and making the at least one second receiving series transistor be cut off; and
in a second mode, making the at least one first receiving series transistor be turned on, and making the at least one second receiving series transistor be turned on.
